(19) United States
(12) Patent Application Publication
(10) Pub. No.: US 2026/0026063 A1
(43) Pub. Date: Jan. 22, 2026

(54) Memory Circuitry And Methods Used In Forming Memory Circuitry

(71) Applicant: Micron Technology, Inc., Boise, ID (US)

(72) Inventors: Kamal M. Karda, Boise, ID (US); Haitao Liu, Boise, ID (US); Chandra Mouli, Boise, ID (US); Si-Woo Lee, Saratoga, CA (US)

(73) Assignee: Micron Technology, Inc., Boise, ID (US)

(21) Appl. No.: 19/248,767

(22) Filed: Jun. 25, 2025

Related U.S. Application Data
(60) Provisional application No. 63/674,137, filed on Jul. 22, 2024.

(51) Int. Cl. H10D 62/832; H10B 12/00; H10D 1/68; H10D 62/10; H10D 62/13; H10D 62/60; H10D 62/83

(52) U.S. Cl. CPC H10D 62/832; H10B 12/05; H10B 12/482; H10D 1/714; H10D 62/118; H10D 62/151; H10D 62/60; H10D 62/83

(57) ABSTRACT

Memory circuitry comprises vertically-alternating tiers of insulative material and memory cells. The memory cells individually comprise a transistor having a channel region horizontally between first and second source/drain regions and a gate operatively-proximate the channel region. The memory cells comprise a capacitor comprising a first capacitor electrode, a second capacitor electrode, and a capacitor insulator between the first and second capacitor electrodes. The first capacitor electrode is directly electrically coupled to the first source/drain region. The second capacitor electrode of multiple of the capacitors are directly electrically coupled with one another. Digitlines extend through the vertically-alternating tiers. Individual of the second source/drain regions of individual of the transistors that are in different memory-cell tiers are directly electrically coupled to individual of the digitlines. The second source/drain regions individually comprise conductively-doped SiₓGe₁₋ₓ, where x is 0 to 0.97. Methods are disclosed.

### TECHNICAL FIELD

Embodiments disclosed herein pertain to memory circuitry and to methods used in forming memory circuitry.

### BACKGROUND

Memory is one type of integrated circuitry and is used in computer systems for storing data. Memory may be fabricated in one or more arrays of individual memory cells. Memory cells may be written to, or read from, using digitlines (which may also be referred to as bitlines, data lines, or sense lines) and access lines (which may also be referred to as wordlines). The sense lines may conductively interconnect memory cells along columns of the array, and the access lines may conductively interconnect memory cells along rows of the array. Each memory cell may be uniquely addressed through the combination of a sense line and an access line.

Memory cells may be volatile, semi-volatile, or non-volatile. Non-volatile memory cells can store data for extended periods of time in the absence of power. Non-volatile memory is conventionally specified to be memory having a retention time of at least about 10 years. Volatile memory dissipates and is therefore refreshed/rewritten to maintain data storage. Volatile memory may have a retention time of milliseconds or less. Regardless, memory cells are configured to retain or store memory in at least two different selectable states. In a binary system, the states are considered as either a “0” or a “1”. In other systems, at least some individual memory cells may be configured to store more than two levels or states of information.

Memory cells may be arranged or arrayed in several manners including, for example, in a vertical stack (e.g., along a z direction) comprising a three-dimensional (3D) memory array region having horizontal tiers in which individual memory cells are received (e.g., arrayed in x and y directions). The stack in the 3D memory array region comprises vertically-alternating insulative tiers and conductive tiers that extend into a stair-step region. The stair-step region includes individual “stairs” (alternately termed “steps” or “stair-steps”) that define contact regions of conductive lines of individual of the conductive tiers to which vertical conductive vias can contact to provide electrical access to/from those conductive lines.

### BRIEF DESCRIPTION OF THE DRAWINGS

FIG. 1 is a diagrammatic schematic of a DRAM memory array and peripheral circuitry in accordance with the prior art and in accordance with an embodiment of the invention.

FIG. 2 is an enlargement of a portion of FIG. 1.

FIGS. 3-14 are diagrammatic sectional views of constructions in accordance with embodiments of the invention.

FIGS. 15-22 are diagrammatic sequential sectional and/or enlarged

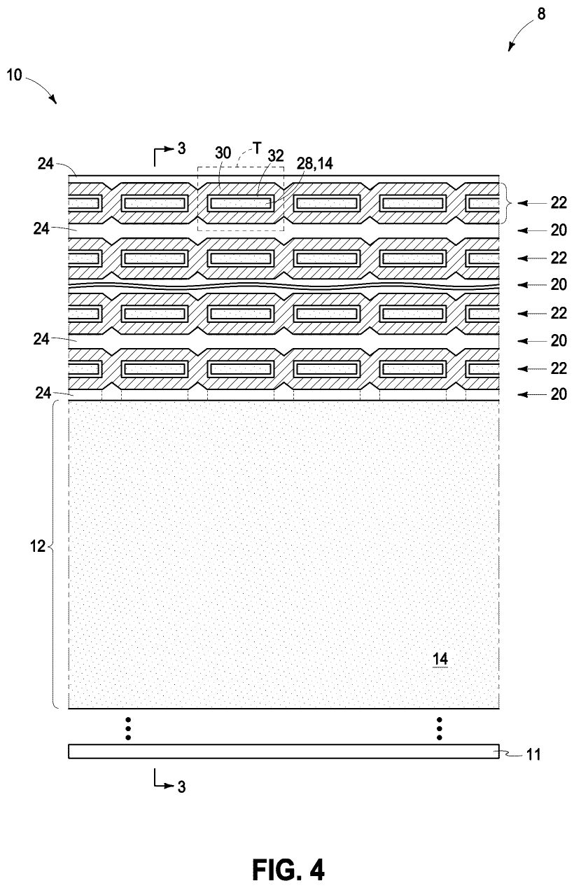

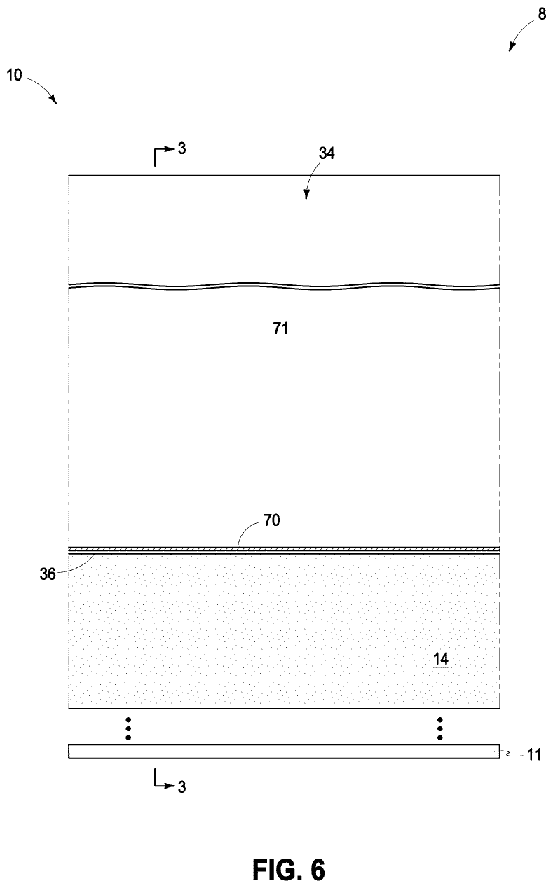

views of the construction of FIGS. 3-7, or portions thereof or alternate and/or additional embodiments, in process in accordance with some embodiments of the invention.

### DETAILED DESCRIPTION OF EXAMPLE EMBODIMENTS

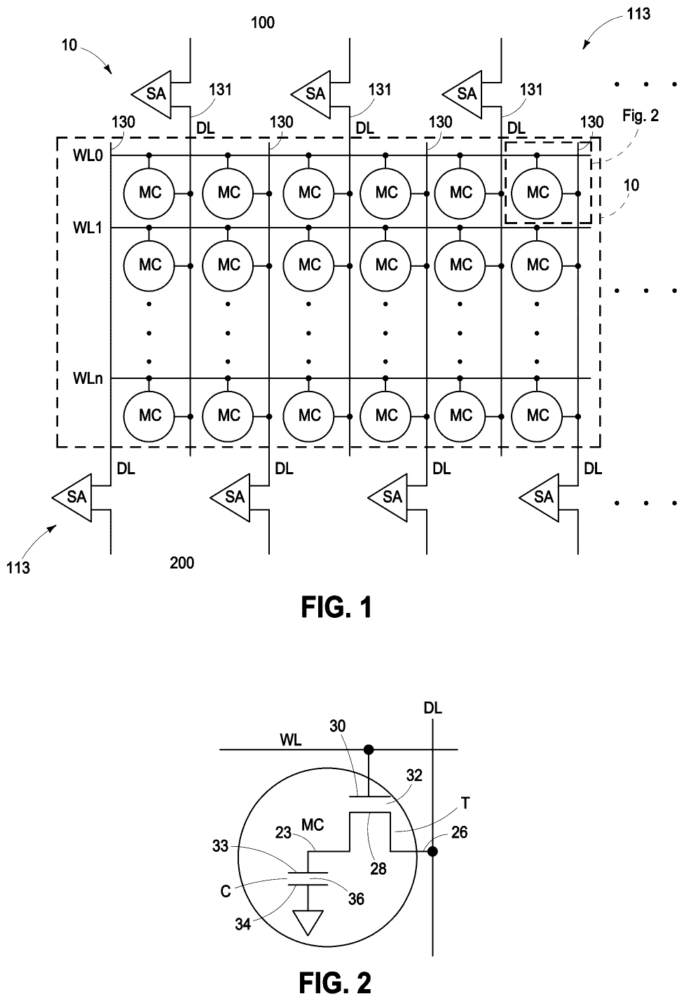

Embodiments of the invention encompass memory circuitry (e.g., DRAM) having vertically-alternating tiers of insulative material and memory cells, with the memory cells individually comprising a capacitor and a horizontally-oriented transistor. Embodiments of the invention also encompass methods used in forming such memory circuitry. Example structure embodiments are first described with reference to FIGS. 1-14.

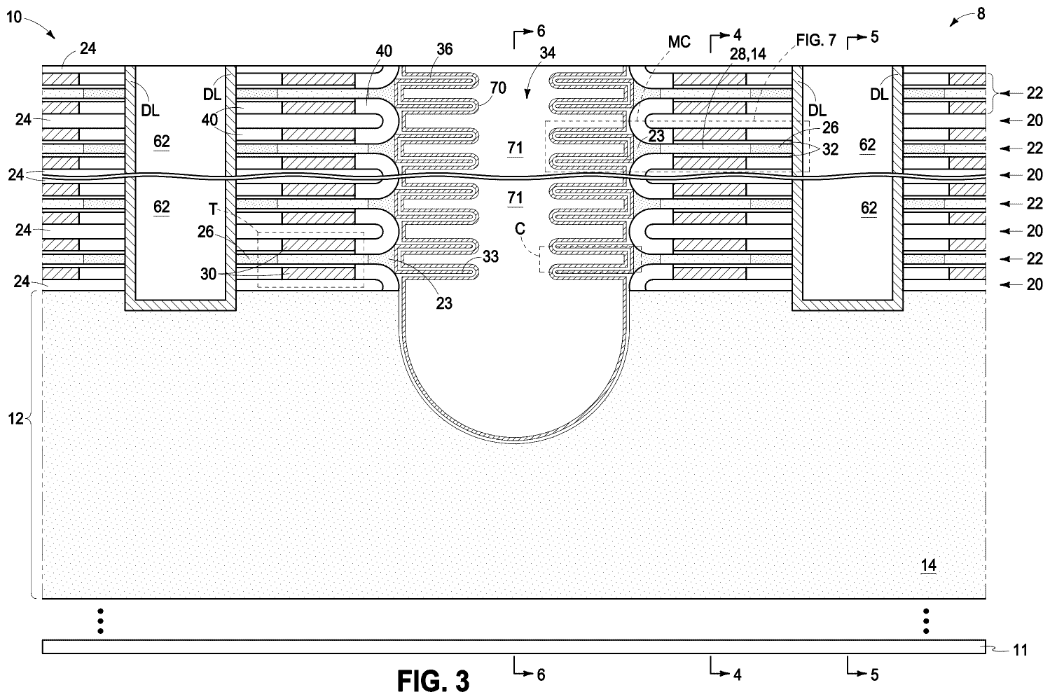

One example prior art schematic diagram of DRAM circuitry, and in accordance with an embodiment of the invention, is shown in FIGS. 1 and 2. FIG. 2 shows example memory cells MC individually comprising a transistor T and a capacitor C. One electrode of capacitor C is directly electrically coupled to a suitable potential (e.g., ground) and the other capacitor electrode is contacted with or comprises one of the source/drain regions of transistor T. The other source/drain region of transistor T is directly electrically coupled with a digitline/sense line 130 or 131 (also individually designated as DL). The gate of transistor T is directly electrically coupled with (e.g., comprises part of) a wordline/access line WL. FIG. 1 shows digitlines 130 and 131 extending from one of opposite sides 100 and 200 of a memory array area 10 into a peripheral circuitry area 113 that is aside memory array area 10. Digitlines 130 and 131 individually directly electrically couple with a sense amp SA on opposite sides 100 and 200 of array area 10 within peripheral circuitry area 113. Sense amps SA could be on only one side or all directly above or directly below memory array area 10. Non-schematic structure embodiments as shown herein in FIG. 3+ have the wordlines/access lines running horizontally and the digitlines/sense lines running vertically.

Referring to FIG. 3-7, an example fragment of a substrate construction 8 comprising array or array area 10 has been fabricated relative to a base substrate 11. Substrate 11 may comprise any one or more of conductive/conductor/conducting, semiconductive/semiconductor/semiconducting, and insulative/insulator/insulating (i.e., electrically herein) materials. Materials may be aside, elevationally inward, or elevationally outward of the FIG. 3—depicted materials. For example, other partially or wholly fabricated components of integrated circuitry may be provided somewhere above, about, or within base substrate 11. Control and/or other peripheral circuitry for operating components within a memory array may also be fabricated and may or may not be wholly or partially within a memory array or sub-array. Further, multiple sub-arrays may also be fabricated and operated independently, in tandem, or otherwise relative one another. As used in this document, a “sub-array” may also be considered as an array.

Memory circuitry (e.g., that of or comprising construction 8) comprises vertically-alternating tiers 20, 22 of insulative material 24 (e.g., silicon dioxide and/or silicon nitride) and memory cells MC, respectively. Example construction 8 comprises a semiconductor substrate 12 (e.g., a bulk wafer comprising monocrystalline silicon 14) above which tiers 20 and 22 are received. Regardless, memory cells MC individually comprise a transistor T comprising a first source/drain region 23, a second source/drain region 26, and a channel region 28 horizontally between the first and second source/drain regions. Regions 23, 26, and 28 of different immediately-horizontally-adjacent memory cells MC into and out of the plane of the page upon which FIG. 3 lies in a common memory-cell tier22 may be isolated relative one another by insulative material (not shown). Transistor T also comprises a gate 30 (e.g., gate-all-around the channel; e.g., conductive metal material) having a gate insulator 32 (e.g., dielectric or ferroelectric) between at least channel region 28 and gate 30. An example insulator 40 (e.g., silicon nitride) is laterally against lateral sides/edges of gates 30.

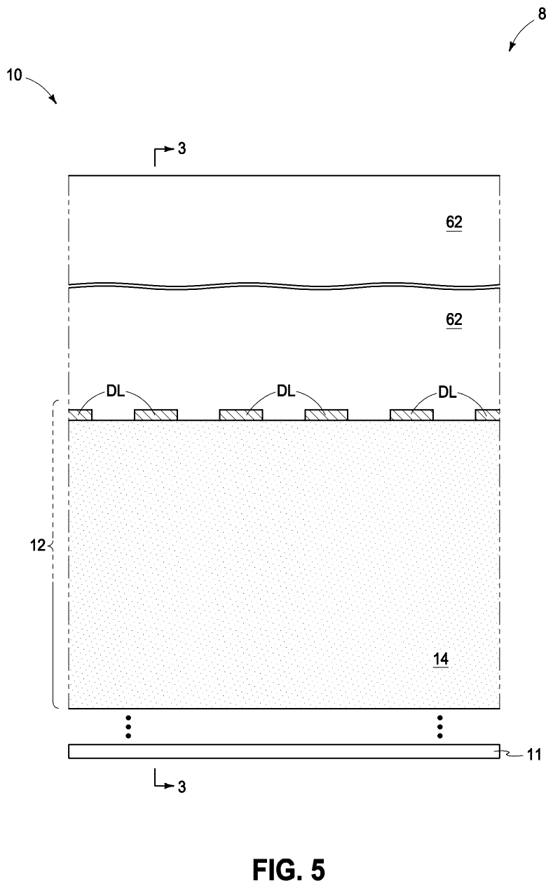

Example capacitor C comprises a first capacitor electrode 33 (e.g., a storage-node electrode), a second capacitor electrode 34 (e.g., comprising conductive metal material 70 and conductively-doped polysilicon 71), and a capacitor insulator 36 there-between (e.g., dielectric or ferroelectric). Second capacitor electrodes 34 of multiple capacitors C are directly electrically coupled with one another. First capacitor electrode 33 is directly coupled to first source/drain region 23 of transistor T. Digitlines DL extend through vertically-alternating tiers 20 and 22. Digitlines DL of different immediately-horizontally-adjacent memory cells MC into and out of the plane of the page upon which FIG. 3 lies in a common memory-cell tier 22 may be isolated relative one another by insulative material 62 (e.g., silicon dioxide and/or silicon nitride). Individual second source/drain regions 26 of individual transistors T that are in different memory-cell tiers 22 are directly electrically coupled to individual digitlines DL. Example insulator material 62 is between immediately-adjacent digitlines DL orthogonal to the vertical cut of FIG. 3, as shown in FIG. 5.

In accordance with structure embodiments of the invention, second source/drain regions 26 individually comprise conductively-doped SiₓGe₁₋ₓ 65, where x is 0 to 0.97, in one embodiment from 0.2 to 0.095, and in one ideal embodiment from 0.5 to 0.8. SiₓGe₁₋ₓ 65 may include additional elements, but ideally consists of or consists essentially of SiₓGe₁₋ₓ. In this document, “conductively-doped” means including a conductivity-increasing dopant at a concentration of at least 1×10¹⁸ atoms/cm³, with an example upper concentration limit being 1×10²² atoms/cm³.

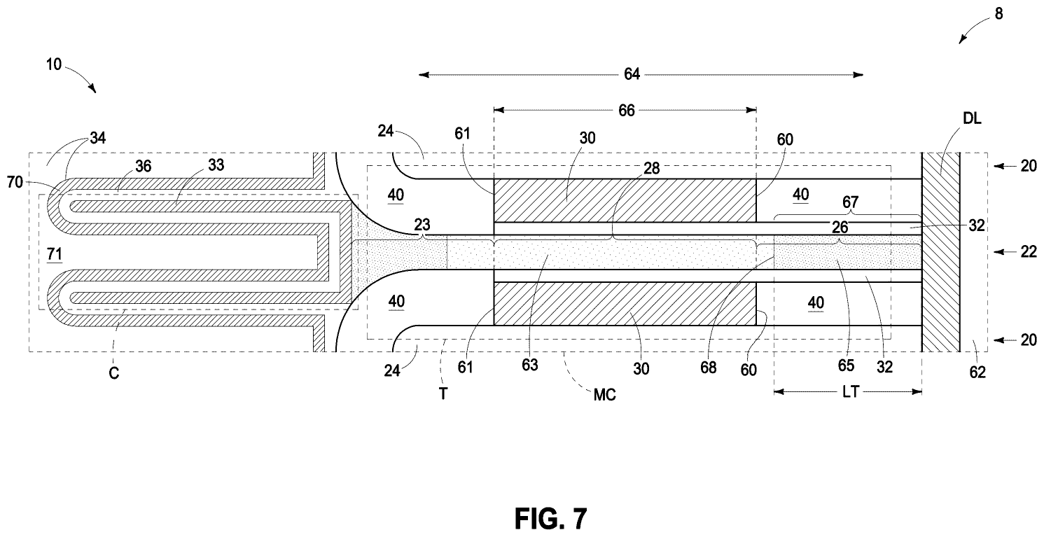

In one embodiment, gate 30 has opposing first and second lateral edges 61 and 60, respectively, in a vertical cross-section (e.g., that of FIGS. 3 and 7). First lateral edge 61 is closest to first source/drain region 23 (in comparison to second lateral edge 60) and second lateral edge 60 is closest to second source/drain region 26 (in comparison to first lateral edge 61). Channel region 28 comprises silicon material 63 that is not conductively doped. In some embodiments, silicon material 63 extends laterally beyond second lateral edge 60 of gate 30 to SiₓGe₁₋ₓ 65 of second source/drain region 26 along a direction 64 of channel length 66 (channel length being the shortest straight-line distance between source/drain regions 23 and 26) to be directly against SiₓGe₁₋ₓ 65 (e.g., to be directly against a lateral edge 68 thereof). In one embodiment, SiₓGe₁₋ₓ 65 has a lateral thickness LT along direction 64 of channel length 66 of 1 nanometer to 60 nanometers, and more ideally of 20 nanometers to 30 nanometers. In one embodiment, silicon material 63 is devoid of germanium. In this document, “devoid of” means from 0 to no more than 1×10¹⁰ atoms/cm³. In one embodiment, silicon material 63 extends laterally beyond first lateral edge 61 of gate 30 to first source/drain region 23 along direction 64 of channel length 66 to be directly against first source/drain region 23. Ideally, a highest-dopant concentration region of second source/drain region 26 (indicated by the highest density stippling thereof) is conductively-doped monocrystalline or polycrystalline silicon.

In one embodiment, conductively-doped SiₓGe₁₋ₓ 65 of the second source/drain region 26 has a region 67 of highest concentration of conductivity-increasing dopant (e.g., P if n-type; e.g., B if p-type). Silicon material 63 that extends laterally beyond second lateral edge 60 of gate 30 has a decreasing dopant concentration (e.g., a decreasing concentration gradient that may or may not be straight linear, and regardless that is not evident from the drawings due to scale) along direction 64 of channel length 66 from region 67 of highest concentration of conductivity-increasing dopant in second source/drain region 26 (e.g., lateral edge 68) towards channel region 28.

In one embodiment, conductively-doped SiₓGe₁₋ₓ 65 of second source/drain region 26 has silicon-germanium composition that varies along its length (i.e., along direction 64). In one such embodiment, atomic Ge concentration in conductively-doped SiₓGe₁₋ₓ 65 may be higher near gate second lateral edge 60 than near digitline DL.

Any other attribute(s) or aspect(s) as shown and/or described herein with respect to other embodiments may be used in the embodiments shown and described with reference to the above embodiments.

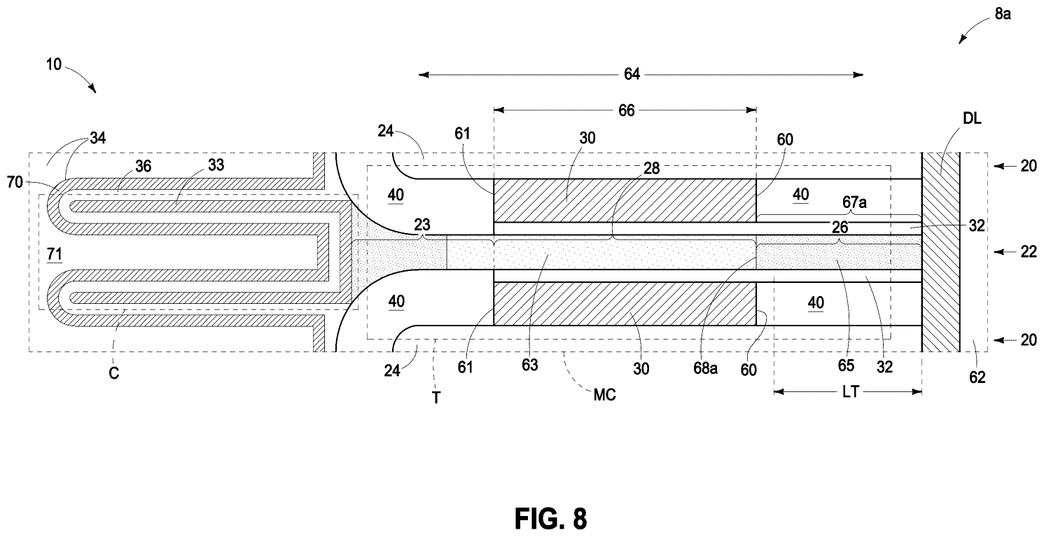

An alternate example construction 8a is shown in FIG. 8. Like numerals from the above-described embodiments have been used where appropriate, with some construction differences being indicated with the suffix “a” or with different numerals. In example construction 8a, SiₓGe₁₋ₓ 65 of second source/drain region 26 (e.g., region 67a) has a lateral edge 68a that is laterally-coincident with second lateral edge 60 of gate 30. Any other attribute(s) or aspect(s) as shown and/or described herein with respect to other embodiments may be used.

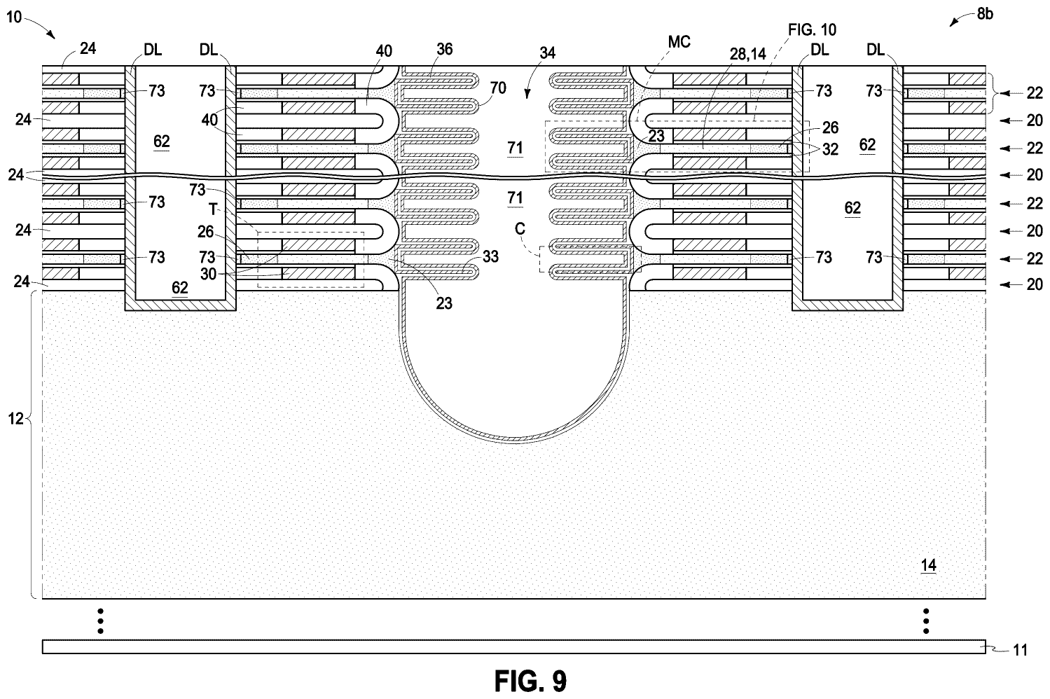

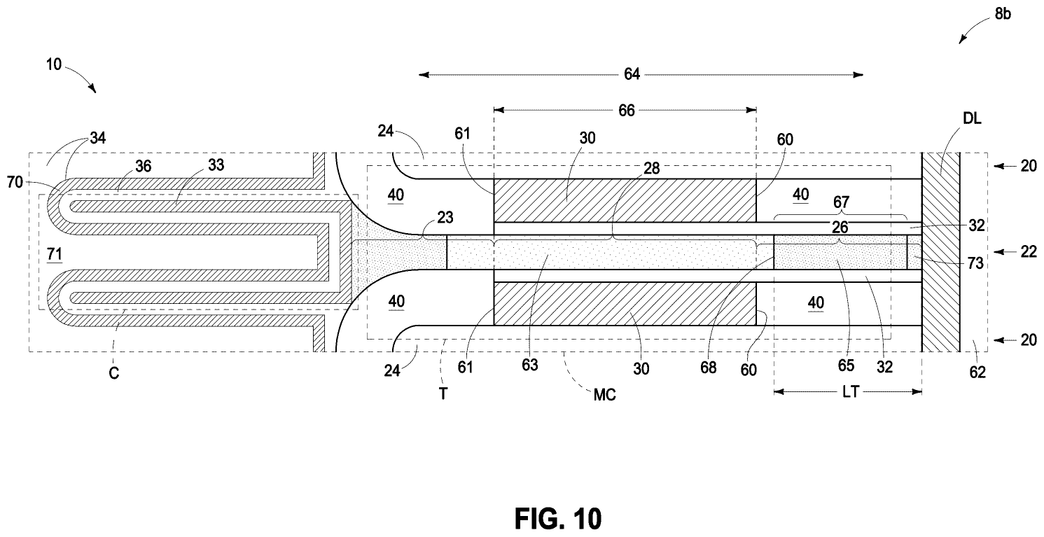

Another alternate example construction 8b is shown in FIGS. 9 and 10. Like numerals from the above-described embodiments have been used where appropriate, with some construction differences being indicated with the suffix “b” or with different numerals. In example construction 8b, second source/drain regions 26 individually comprise conductively-doped SiₓGe₁₋ₓ 65 and conductively-doped silicon material 73 of different composition from that of the SiₓGe₁₋ₓ 65. Conductively-doped silicon material 73 is laterally between SiₓGe₁₋ₓ 65 and the individual digitline DL to which the second source/drain region 26 is directly electrically coupled. In one embodiment, conductively-doped silicon material 73 is devoid of germanium. In one embodiment, conductively-doped silicon material 73 consists of or consists essentially of elemental silicon and a conductivity-increasing dopant (e.g., P for n-type; e.g., B for p-type) that renders conductively-doped silicon material 73 to be conductive. In one embodiment, conductively-doped silicon material 73 is directly against SiₓGe₁₋ₓ 65 and the individual digitline DL to which the second source/drain region 26 is directly electrically coupled.

In one embodiment, conductively-doped silicon material 73 is not vertically continuous along the insulative tiers that are vertically-between immediately-vertically-adjacent memory cell tiers 22 (there not being any other memory cell tier between those that are immediately-vertically-adjacent one another, and as shown), and in one such embodiment conductively-doped silicon material 73 does not extend along any of insulative tiers 20 that are vertically-between immediately-vertically-adjacent memory cell tiers 22 (as shown).

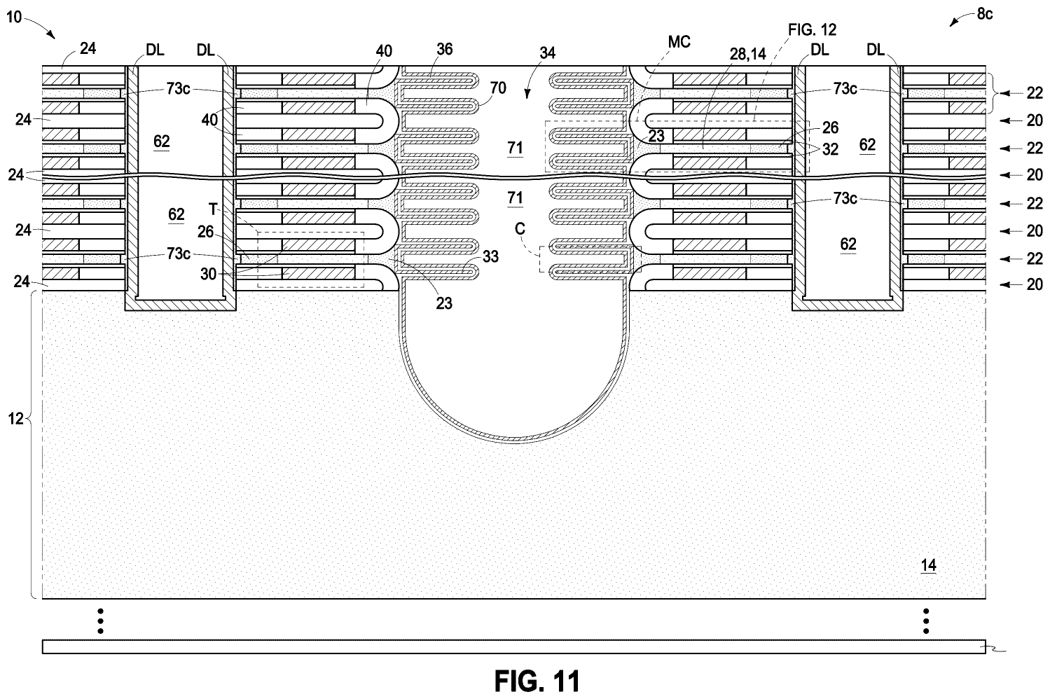

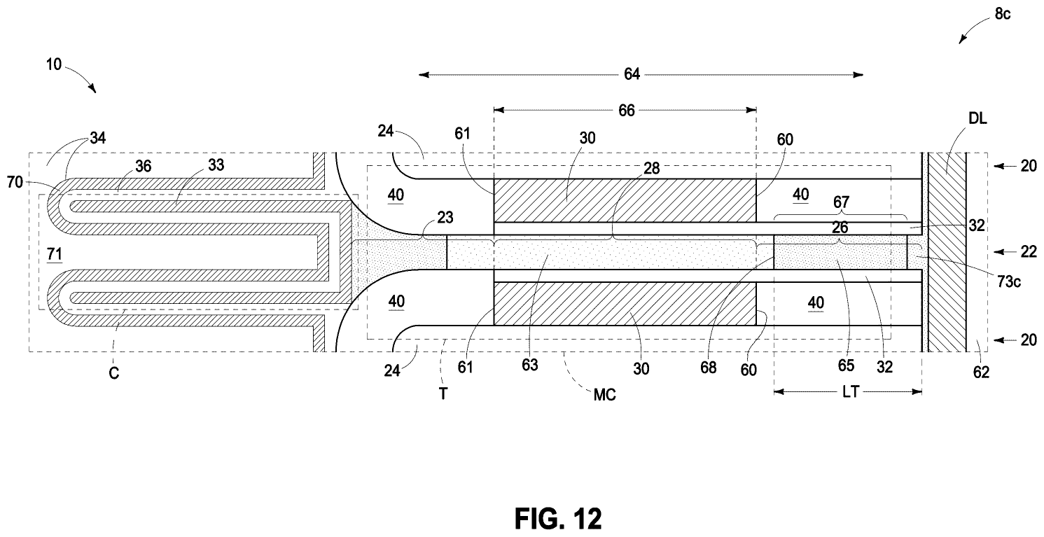

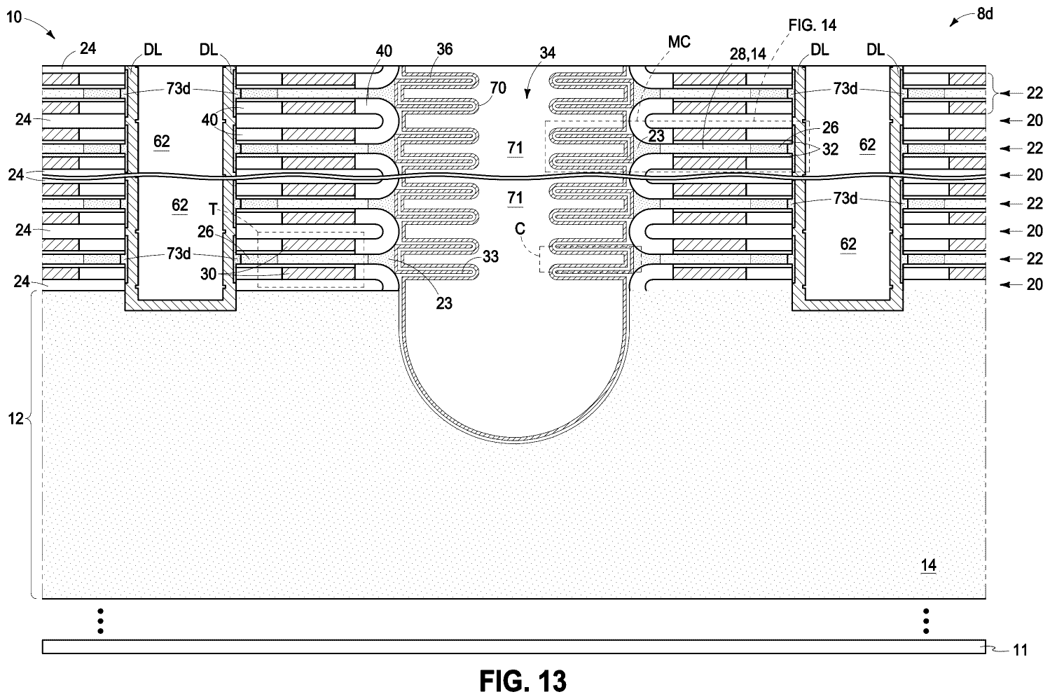

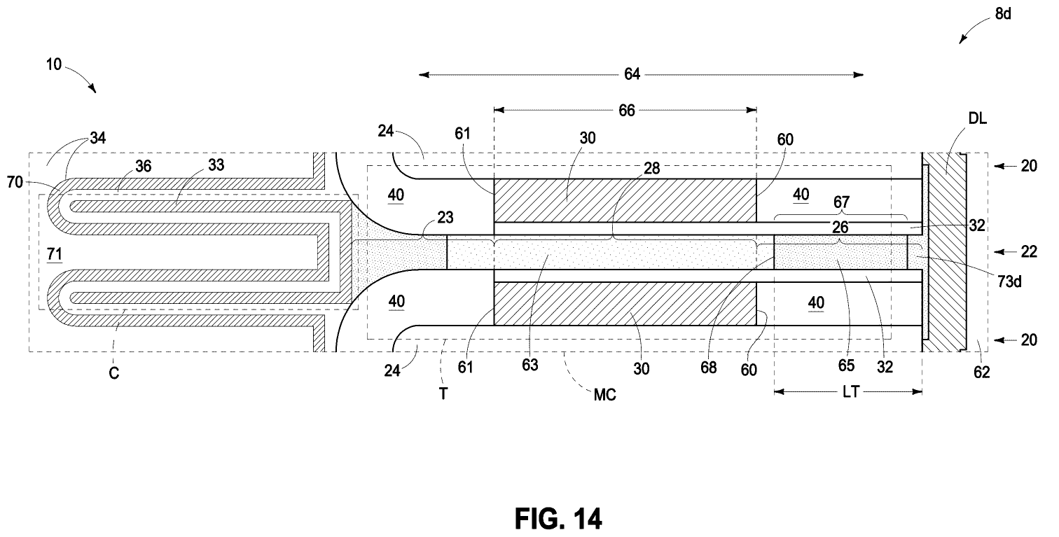

Another alternate example construction 8c is shown in FIGS. 11 and 12. Like numerals from the above-described embodiments have been used where appropriate, with some construction differences being indicated with the suffix “c” or with different numerals. In example construction 8c, conductively-doped silicon material 73c extends elevationally and continuously along multiple of vertically-alternating tiers 20, 22 of insulative material 24 and memory cells MC (as shown), and in one such embodiment such extends elevationally and continuously along all of vertically-alternating tiers 20 and 22 of insulative material 24 and memory cells MC (as shown). FIGS. 13 and 14 show an alternate construction 8d wherein conductively-doped silicon material 73d extends elevationally and continuously along multiple, but not all, of vertically-alternating tiers 20, 22 of insulative material 24 and memory cells MC. Like numerals from the above-described embodiments have been used where appropriate, with some construction differences being indicated with the suffix “d” or with different numerals.

Floating body effect can be problematic particularly in gate-all-around transistor constructions, for example as exemplified herein, and that can adversely impact Iₒₙ and I_{off}. Providing conductively-doped SiₓGe₁₋ₓ 65 at least as part of the source/drain region that is proximate the digitline may at least suppress I_{off} problems.

Embodiments of the invention encompass methods used in forming memory circuitry, by way of example only that incorporates device/structure as referred to above. Nevertheless, the method embodiments may incorporate, form, and/or have any of the attributes described with respect to device embodiments.

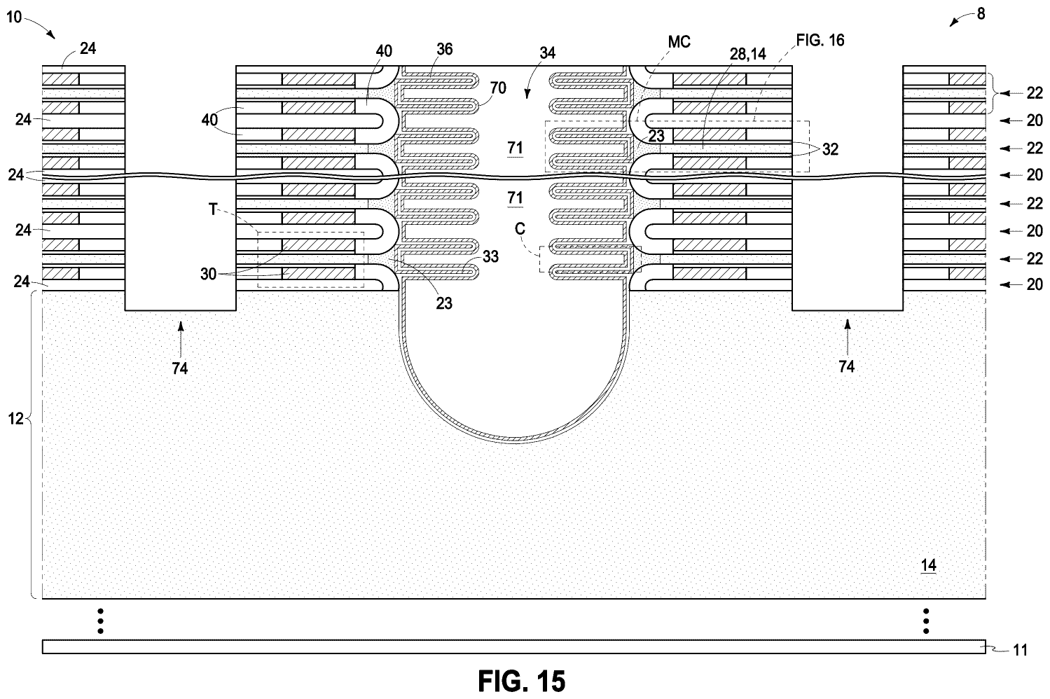

FIGS. 15-22 by way of example sequentially show predecessor constructions 8 in example methods used in forming memory circuitry, with such circuitry comprising memory cells that individually comprise a transistor and a capacitor.

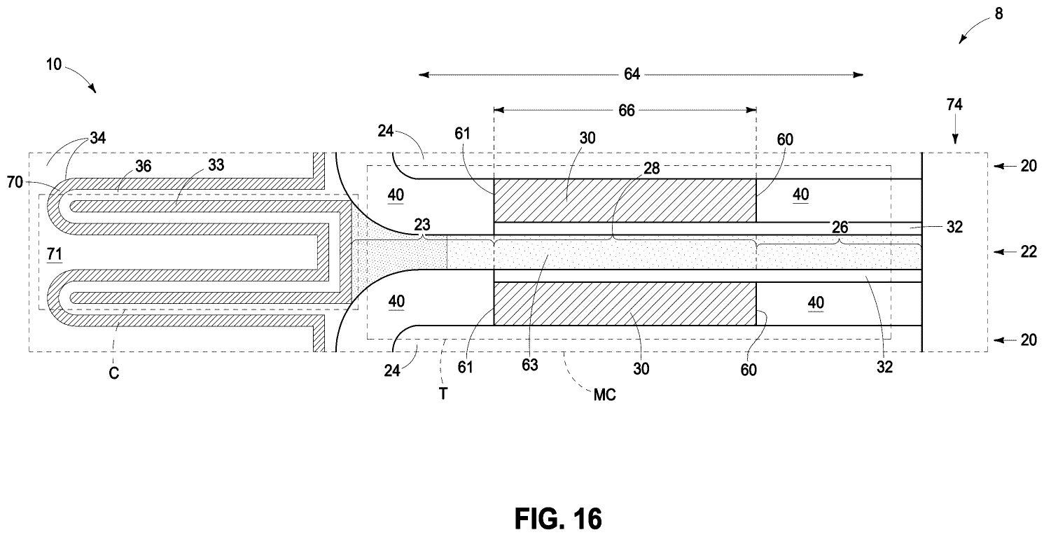

Referring to FIGS. 15 and 16, vertically-alternating tiers 20 and 22 have been formed and that will ultimately comprise vertically alternating insulative tiers 20 and memory-cell tiers MC. Memory-cell tiers MC comprise silicon material (e.g., 63). For example, and as described above, memory-cell tiers 22 will ultimately comprise memory cells MC that individually comprise a transistor having a channel region horizontally between first and second source/drain regions and a gate operatively-proximate the channel region. The first and second source/drain regions at least initially comprise the silicon material and the channel region comprises the silicon material. Memory cells MC will also ultimately comprise a capacitor C comprising a first capacitor electrode 33, a second capacitor electrode 34, and a capacitor insulator 36 between first capacitor electrode 33 and second capacitor electrode 34. First capacitor electrode 33 is ultimately directly electrically coupled to first source/drain region 23. Second capacitor electrode 34 of multiple capacitors C are directly electrically coupled with one another. Construction 8 includes parallel and spaced digitline trenches 74 that extend through vertically-alternating insulative and memory-cell tiers 20 and 22. In this document, a “digitline trench” is a trench in which a digitline has been or will be formed. Capacitors C are shown, by way of example only, as being formed before forming digitline trenches 74. Alternately, such could be formed after forming such trenches and/or after some or all the example processing described below. Regardless, example manners not material to the inventions disclosed herein in forming that which is shown in FIGS. 15 and 16 are, for example, shown in Micron Technology's U.S. Patent Application Publication Nos. 2022/0254784, 2022/0130834, U.S. Pat. No. 11,342,218, etc.

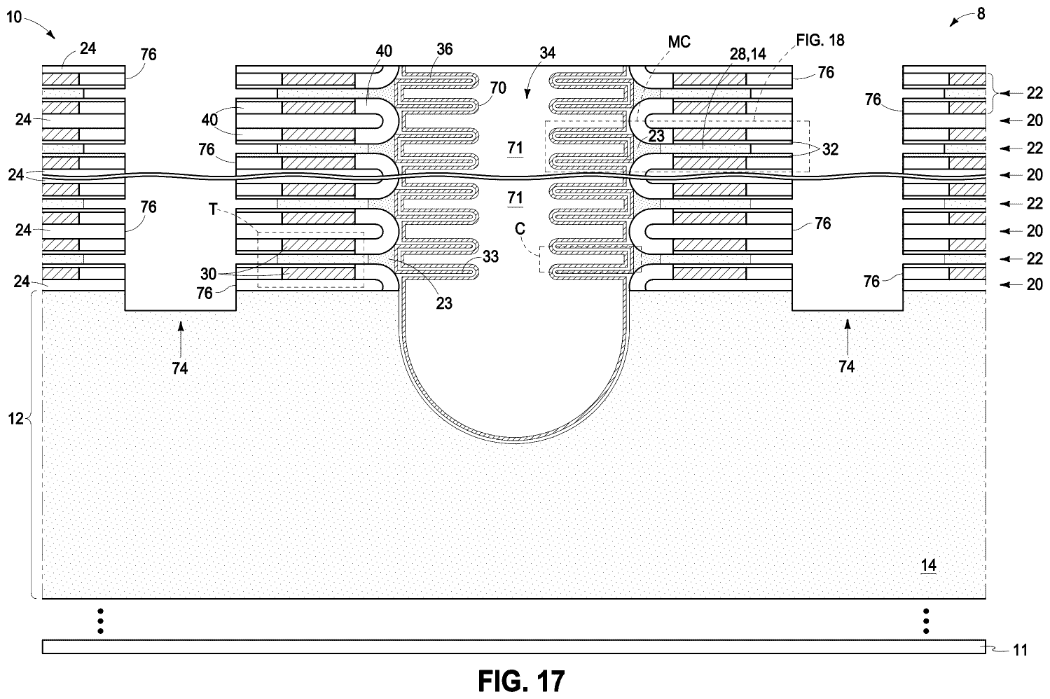

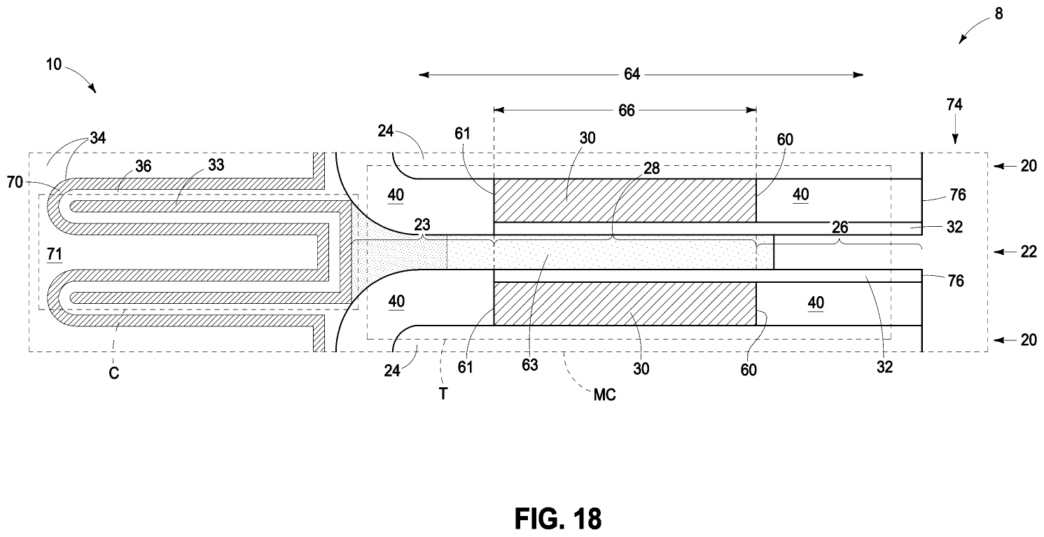

Referring to FIGS. 17 and 18, through the digitline trenches 74, silicon material 63 in memory-cell tiers 22 has been laterally recessed (e.g., by etching) relative to sidewalls 76 of digitline trenches 74.

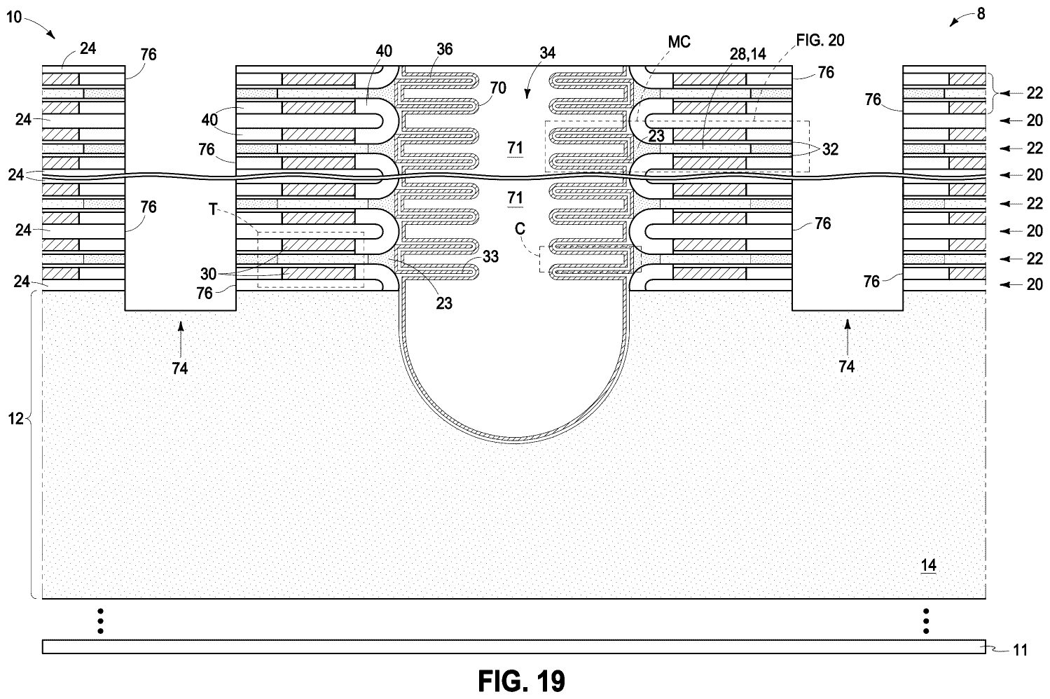

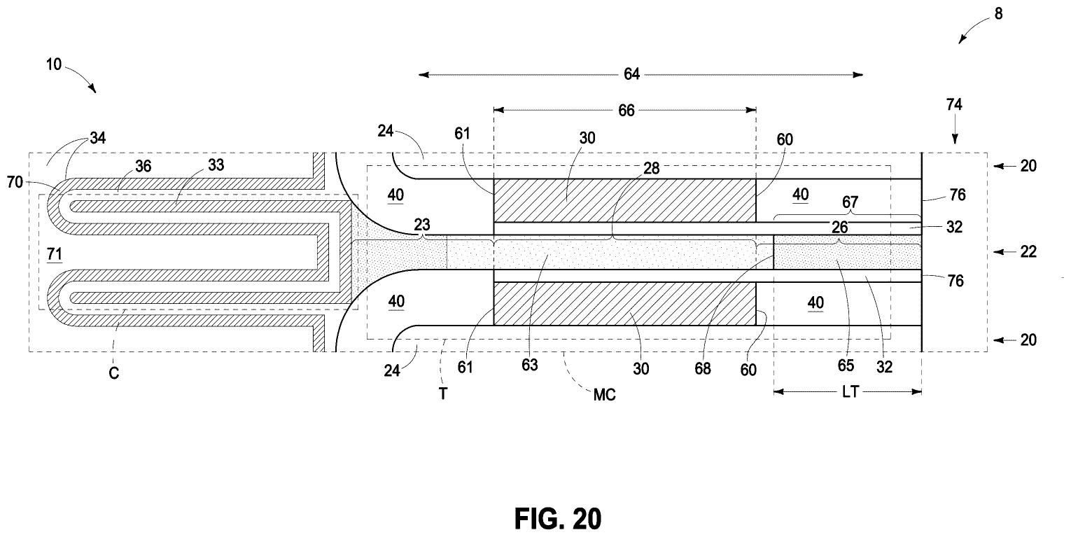

Referring to FIGS. 19 and 20, conductively-doped SiₓGe₁₋ₓ, 65 has been epitaxially formed from recessed silicon material 63, with epitaxially-grown SiₓGe₁₋ₓ 65 being of different composition from that of silicon material 63 and comprising second source/drain region 26 of individual transistors T. An example manner of epitaxially forming silicon material 14 includes using SiH₄, Si₂H₆, H₂SiCl₂, GeH₄, HCl, Cl₂, and a suitable conductivity-dopant source gas (e.g., a phosphine, a borane, etc.) as precursors at 300° C. to 1,500° C. and 100 mTorr to 100 Torr.

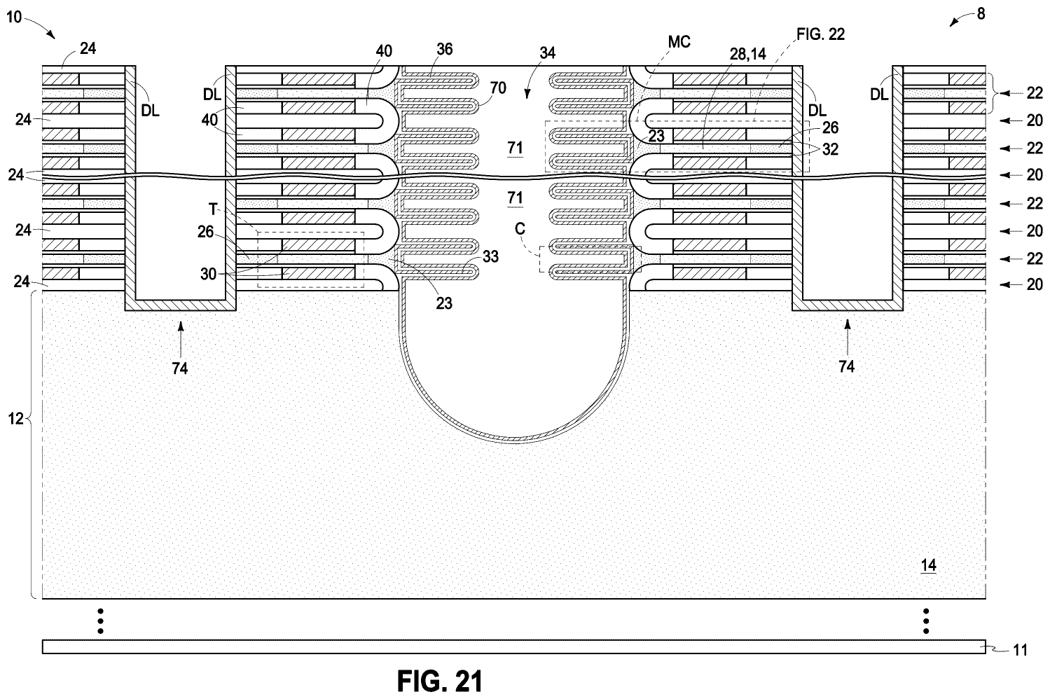

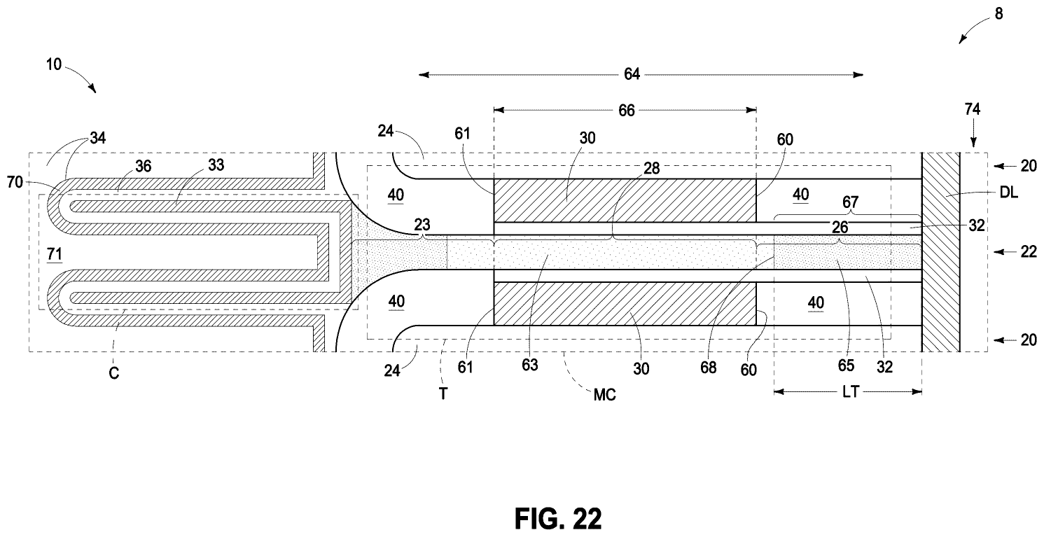

Referring to FIGS. 21 and 22, a digitline DL has been formed to extend through vertically-alternating insulative tiers 20 and memory-cell tiers 22 in individual digitline trenches 74 (e.g., two per digitline trench 74 being shown). Individual second source/drain regions 26 of individual transistors T that are in different memory-cell tiers 22 are directly electrically coupled to individual digitlines DL. Conductively-doped silicon material 73 (not shown in FIGS. 21 and 22) may for formed (e.g., by epitaxially growing such from epitaxially-grown SiₓGe₁₋ₓ 65 and/or by other method[s]) prior to forming digitlines DL, for example to form any of the constructions of FIGS. 9-14. Regardless, insulator material 62 may be subsequently formed.

The above processing(s) or construction(s) may be considered as being relative to an array of components formed as or within a single stack or single deck of such components above or as part of an underlying base substrate (albeit, the single stack/deck may have multiple tiers). Control and/or other peripheral circuitry for operating or accessing such components within an array may also be formed anywhere as part of the finished construction, and in some embodiments may be under the array (e.g., CMOS under-array). Regardless, one or more additional such stack(s)/deck(s) may be provided or fabricated above and/or below that shown in the figures or described above. Further, the array(s) of components may be the same or different relative one another in different stacks/decks and different stacks/decks may be of the same thickness or of different thicknesses relative one another. Intervening structure may be provided between immediately-vertically-adjacent stacks/decks (e.g., additional circuitry and/or dielectric layers). Also, different stacks/decks may be electrically coupled relative one another. The multiple stacks/decks may be fabricated separately and sequentially (e.g., one atop another), or two or more stacks/decks may be fabricated at essentially the same time.

The assemblies and structures discussed above may be used in integrated circuits/circuitry and may be incorporated into electronic systems. Such electronic systems may be used in, for example, memory modules, device drivers, power modules, communication modules, processor modems, and application-specific modules, and may include multilayer, multichip modules. The electronic systems may be any of a broad range of systems, such as, for example, cameras, wireless devices, displays, chip sets, set top boxes, games, lighting, vehicles, clocks, televisions, cell phones, personal computers, automobiles, industrial control systems, aircraft, etc.

In this document unless otherwise indicated, “elevational”, “higher”, “upper”, “lower”, “top”, “atop”, “bottom”, “above”, “below”, “under”, “beneath”, “up”, and “down” are generally with reference to the vertical direction. “Horizontal” refers to a general direction (i.e., within 10 degrees) along a primary substrate surface and may be relative to which the substrate is processed during fabrication, and vertical is a direction generally orthogonal thereto. Reference to “exactly horizontal” is the direction along the primary substrate surface (i.e., no degrees there-from) and may be relative to which the substrate is processed during fabrication. Further, “vertical” and “horizontal” as used herein are generally perpendicular directions relative one another and independent of orientation of the substrate in three-dimensional space. Additionally, “elevationally-extending” and “extend(ing) elevationally” refer to a direction that is angled away by at least 45° from exactly horizontal. Further, “extend(ing) elevationally”, “elevationally-extending”, “extend(ing) horizontally”, “horizontally-extending” and the like with respect to a field effect transistor are with reference to orientation of the transistor's channel length along which current flows in operation between the source/drain regions. For bipolar junction transistors, “extend(ing) elevationally” “elevationally-extending”, “extend(ing) horizontally”, “horizontally-extending” and the like, are with reference to orientation of the base length along which current flows in operation between the emitter and collector. In some embodiments, any component, feature, and/or region that extends elevationally extends vertically or within 10° of vertical.

Further, “directly above”, “directly below”, and “directly under” require at least some lateral overlap (i.e., horizontally) of two stated regions/materials/components relative one another. Also, use of “above” not preceded by “directly” only requires that some portion of the stated region/material/component that is above the other be elevationally outward of the other (i.e., independent of whether there is any lateral overlap of the two stated regions/materials/components). Analogously, use of “below” and “under” not preceded by “directly” only requires that some portion of the stated region/material/component that is below/under the other be elevationally inward of the other (i.e., independent of whether there is any lateral overlap of the two stated regions/materials/components).

Any of the materials, regions, and structures described herein may be homogenous or non-homogenous, and regardless may be continuous or discontinuous over any material which such overlie. Where one or more example composition(s) is/are provided for any material, that material may comprise, consist essentially of, or consist of such one or more composition(s). Further, unless otherwise stated, each material may be formed using any suitable existing or future-developed technique, with atomic layer deposition, chemical vapor deposition, physical vapor deposition, epitaxial growth, diffusion doping, and ion implanting being examples.

Additionally, “thickness” by itself (no preceding directional adjective) is defined as the mean straight-line distance through a given material or region perpendicularly from a closest surface of an immediately-adjacent material of different composition or of an immediately-adjacent region. Additionally, the various materials or regions described herein may be of substantially constant thickness or of variable thicknesses. If of variable thickness, thickness refers to average thickness unless otherwise indicated, and such material or region will have some minimum thickness and some maximum thickness due to the thickness being variable. As used herein, “different composition” only requires those portions of two stated materials or regions that may be directly against one another to be chemically and/or physically different, for example if such materials or regions are not homogenous. If the two stated materials or regions are not directly against one another, “different composition” only requires that those portions of the two stated materials or regions that are closest to one another be chemically and/or physically different if such materials or regions are not homogenous. In this document, a material, region, or structure is “directly against” another when there is at least some physical touching contact of the stated materials, regions, or structures relative one another. In contrast, “over”, “on”, “adjacent”, “along”, and “against” not preceded by “directly” encompass “directly against” as well as construction where intervening material(s), region(s), or structure(s) result(s) in no physical touching contact of the stated materials, regions, or structures relative one another.

Herein, regions-materials-components are “electrically coupled” relative one another if in normal operation electric current is capable of continuously flowing from one to the other and does so predominately by movement of subatomic positive and/or negative charges when such are sufficiently generated. Another electronic component may be between and electrically coupled to the regions-materials-components. In contrast, when regions-materials-components are referred to as being “directly electrically coupled”, no intervening electronic component (e.g., no diode, transistor, resistor, transducer, switch, fuse, etc.) is between the directly electrically coupled regions-materials-components.

Any use of “row” and “column” in this document is for convenience in distinguishing one series or orientation of features from another series or orientation of features and along which components have been or may be formed. “Row” and “column” are used synonymously with respect to any series of regions, components, and/or features independent of function. Regardless, the rows may be straight and/or curved and/or parallel and/or not parallel relative one another, as may be the columns. Further, the rows and columns may intersect relative one another at 90° or at one or more other angles (i.e., other than the straight angle).

The composition of any of the conductive/conductor/conducting materials herein may be conductive metal material and/or conductively-doped semiconductive/semiconductor/semiconducting material. “Metal material” is any one or combination of an elemental metal, any mixture or alloy of two or more elemental metals, and any one or more metallic compound(s).

Herein, any use of “selective” as to etch, etching, removing, removal, depositing, forming, and/or formation is such an act of one stated material relative to another stated material(s) so acted upon at a rate of at least 2:1 by volume. Further, any use of selectively depositing, selectively growing, or selectively forming is depositing, growing, or forming one material relative to another stated material or materials at a rate of at least 2:1 by volume for at least the first 75 Angstroms of depositing, growing, or forming.

Unless otherwise indicated, use of “or” herein encompasses either and both.

### CONCLUSION

In some embodiments, memory circuitry comprises vertically-alternating tiers of insulative material and memory cells. The memory cells individually comprise a transistor having a channel region horizontally between first and second source/drain regions and a gate operatively-proximate the channel region. A capacitor comprises a first capacitor electrode, a second capacitor electrode, and a capacitor insulator between the first and second capacitor electrodes. The first capacitor electrode is directly electrically coupled to the first source/drain region. The second capacitor electrode of multiple of the capacitors are directly electrically coupled with one another. Digitlines extend through the vertically-alternating tiers. Individual of the second source/drain regions of individual of the transistors that are in different memory-cell tiers are directly electrically coupled to individual of the digitlines. The second source/drain regions individually comprise conductively-doped SiₓGe₁₋ₓ, where x is 0 to 0.97.

In some embodiments, memory circuitry comprises vertically-alternating tiers of insulative material and memory cells. The memory cells individually comprise a transistor having a channel region horizontally between first and second source/drain regions and a gate operatively-proximate the channel region. A capacitor comprises a first capacitor electrode, a second capacitor electrode, and a capacitor insulator between the first and second capacitor electrodes. The first capacitor electrode is directly electrically coupled to the first source/drain region. The second capacitor electrode of multiple of the capacitors are directly electrically coupled with one another. Digitlines extend through the vertically-alternating tiers. Individual of the second source/drain regions of individual of the transistors that are in different memory-cell tiers are directly electrically coupled to individual of the digitlines. The second source/drain regions individually comprise conductively-doped SiₓGe₁₋ₓ, where x is 0 to 0.97, and conductively-doped silicon material of different composition from that of the SiₓGe₁₋ₓ. The conductively-doped silicon material is laterally between the SiₓGe₁₋ₓ and the individual digitline to which the second source/drain region is directly electrically coupled.

In some embodiments, a method used in forming memory circuitry comprises forming vertically-alternating tiers that ultimately comprise vertically alternating insulative tiers and memory-cell tiers. The memory-cell tiers comprise silicon material. The memory-cell tiers ultimately comprise memory cells that individually comprise a transistor having a channel region horizontally between first and second source/drain regions and a gate operatively-proximate the channel region. The first and second source/drain regions at least initially comprise the silicon material and the channel region comprises the silicon material. A capacitor comprises a first capacitor electrode, a second capacitor electrode, and a capacitor insulator between the first and second capacitor electrodes. The first capacitor electrode is directly electrically coupled to the first source/drain region. The second capacitor electrode of multiple of the capacitors are directly electrically coupled with one another. Parallel and spaced digitline trenches extend through the vertically-alternating insulative and memory-cell tiers. Through the digitline trenches, the silicon material in the memory-cell tiers is laterally recessed relative to sidewalls of the digitline trenches. Conductively-doped SiₓGe₁₋ₓ, where x is 0 to 0.97, is epitaxially grown from the recessed silicon material. The epitaxially-grown SiₓGe₁₋ₓ is of different composition from that of the silicon material and comprises the second source/drain region of individual of the transistors. A digitline extending through the vertically-alternating insulative tiers and memory-cell tiers is formed in individual of the digitline trenches. Individual of the second source/drain regions of individual of the transistors that are in different memory-cell tiers are directly electrically coupled to individual of the digitlines.

In compliance with the statute, the subject matter disclosed herein has been described in language more or less specific as to structural and methodical features. It is to be understood, however, that the claims are not limited to the specific features shown and described, since the means herein disclosed comprise example embodiments. The claims are thus to be afforded full scope as literally worded, and to be appropriately interpreted in accordance with the doctrine of equivalents.

1. Memory circuitry comprising:
vertically-alternating tiers of insulative material and memory cells, the memory cells individually comprising:
a transistor having a channel region horizontally between first and second source/drain regions and a gate operatively-proximate the channel region; and
a capacitor comprising a first capacitor electrode, a second capacitor electrode, and a capacitor insulator between the first and second capacitor electrodes; the first capacitor electrode being directly electrically coupled to the first source/drain region, the second capacitor electrode of multiple of the capacitors being directly electrically coupled with one another;
digitlines extending through the vertically-alternating tiers, individual of the second source/drain regions of individual of the transistors that are in different memory-cell tiers being directly electrically coupled to individual of the digitlines; and
the second source/drain regions individually comprising conductively-doped SiₓGe₁₋ₓ, where x is 0 to 0.97.

2. The memory circuitry of claim 1 wherein x is 0.2 to 0.95.

3. The memory circuitry of claim 2 wherein x is 0.5 to 0.8.

4. The memory circuitry of claim 1 wherein the gate has opposing first and second lateral edges in a vertical cross-section, the first lateral edge being closest to the first source/drain region, the second lateral edge being closest to the second source/drain region, the channel region comprising silicon material that is not conductively doped, the silicon material extending laterally beyond the second lateral edge of the gate to the SiₓGe₁₋ₓ of the second source/drain region along a direction of channel length to be directly against the SiₓGe₁₋ₓ.

5. The memory circuitry of claim 4 wherein the SiₓGe₁₋ₓ has a lateral thickness along the direction of channel length of 1 nanometer to 60 nanometers.

6. The memory circuitry of claim 5 wherein the SiₓGe₁₋ₓ has a lateral thickness along the direction of channel length of 20 nanometers to 30 nanometers.

7. The memory circuitry of claim 4 wherein the conductively-doped SiₓGe₁₋ₓ of the second source/drain region has a region of highest concentration of conductivity-increasing dopant, the silicon material that extends laterally beyond the second lateral edge of the gate having a decreasing dopant concentration along the direction of channel length from the region of highest concentration of conductivity-increasing dopant in the second source/drain region towards the channel region.

8. The memory circuitry of claim 4 wherein the silicon material is devoid of germanium.

9. The memory circuitry of claim 1 wherein the gate has opposing first and second lateral edges in a vertical cross-section, the first lateral edge being closest to the first source/drain region, the second lateral edge being closest to the second source/drain region, the channel region comprising silicon material that is not conductively doped, the silicon material extending laterally beyond the first lateral edge of the gate to the first source/drain region along a direction of channel length to be directly against the first source/drain region.

10. The memory circuitry of claim 9 wherein the silicon material is devoid of germanium.

11. The memory circuitry of claim 1 wherein the gate has opposing first and second lateral edges in a vertical cross-section, the first lateral edge being closest to the first source/drain region, the second lateral edge being closest to the second source/drain region, the SiₓGe₁₋ₓ of the second source/drain region having a lateral edge that is laterally-coincident with the second lateral edge of the gate.

12. The memory circuitry of claim 1 wherein silicon-germanium composition of the conductively-doped SiₓGe₁₋ₓ varies along its length.

13. The memory circuitry of claim 12 wherein atomic Ge concentration in the conductively-doped SiₓGe₁₋ₓ is higher near the gate than near the individual digitline.

14. Memory circuitry comprising:
vertically-alternating tiers of insulative material and memory cells, the memory cells individually comprising:
a transistor having a channel region horizontally between first and second source/drain regions and a gate operatively-proximate the channel region; and
a capacitor comprising a first capacitor electrode, a second capacitor electrode, and a capacitor insulator between the first and second capacitor electrodes; the first capacitor electrode being directly electrically coupled to the first source/drain region, the second capacitor electrode of multiple of the capacitors being directly electrically coupled with one another;
digitlines extending through the vertically-alternating tiers, individual of the second source/drain regions of individual of the transistors that are in different memory-cell tiers being directly electrically coupled to individual of the digitlines; and
the second source/drain regions individually comprising conductively-doped SiₓGe₁₋ₓ, where x is 0 to 0.97, and conductively-doped silicon material of different composition from that of the SiₓGe₁₋ₓ, the conductively-doped silicon material being laterally between the SiₓGe₁₋ₓ and the individual digitline to which the second source/drain region is directly electrically coupled.

15. The memory circuitry of claim 14 wherein the conductively-doped silicon material is devoid of germanium.

16. The memory circuitry of claim 14 wherein the conductively-doped silicon material consists of or consists essentially of elemental silicon and a conductivity-increasing dopant that renders the conductively-doped silicon material to be conductive.

17. The memory circuitry of claim 14 wherein the conductively-doped silicon material is directly against the SiₓGe₁₋ₓ and the individual digitline to which the second source/drain region is directly electrically coupled.

18. The memory circuitry of claim 14 wherein the conductively-doped silicon material extends elevationally and continuously along multiple of the vertically-alternating tiers of insulative material and memory cells.

19. The memory circuitry of claim 18 wherein the conductively-doped silicon material extends elevationally and continuously along all of the vertically-alternating tiers of insulative material and memory cells.

20. The memory circuitry of claim 14 wherein the conductively-doped silicon material is not vertically continuous along the insulative tiers that are vertically-between immediately-vertically-adjacent of the memory cell tiers.

21. The memory circuitry of claim 20 wherein the conductively-doped silicon material does not extend along any of the insulative tiers that are vertically-between immediately-vertically-adjacent of the memory cell tiers.

22. The memory circuitry of claim 14 wherein silicon-germanium composition of the conductively-doped SiₓGe₁₋ₓ varies along its length.

23. The memory circuitry of claim 22 wherein atomic Ge concentration in the conductively-doped SiₓGe₁₋ₓ is higher near the gate than near the individual digitline.

24. A method used in forming memory circuitry, comprising:
forming vertically-alternating tiers that ultimately comprise vertically alternating insulative tiers and memory-cell tiers, the memory-cell tiers comprising silicon material, the memory-cell tiers ultimately comprising memory cells that individually comprise:
a transistor having a channel region horizontally between first and second source/drain regions and a gate operatively-proximate the channel region, the first and second source/drain regions at least initially comprising the silicon material and the channel region comprising the silicon material; and
a capacitor comprising a first capacitor electrode, a second capacitor electrode, and a capacitor insulator between the first and second capacitor electrodes; the first capacitor electrode being directly electrically coupled to the first source/drain region, the second capacitor electrode of multiple of the capacitors being directly electrically coupled with one another;
forming parallel and spaced digitline trenches extending through the vertically-alternating insulative and memory-cell tiers;
through the digitline trenches, laterally recessing the silicon material in the memory-cell tiers relative to sidewalls of the digitline trenches;
epitaxially growing conductively-doped SiₓGe₁₋ₓ, where x is 0 to 0.97, from the recessed silicon material, the epitaxially-grown SiₓGe₁₋ₓ being of different composition from that of the silicon material and comprising the second source/drain region of individual of the transistors; and
forming a digitline extending through the vertically-alternating insulative tiers and memory-cell tiers in individual of the digitline trenches, individual of the second source/drain regions of individual of the transistors that are in different memory-cell tiers being directly electrically coupled to individual of the digitlines.
